(19) United States
(12) Patent Application Publication
(10) Pub. No.: US 2026/0182394 A1
(43) Pub. Date: Jun. 25, 2026

(54) INTEGRATED CIRCUIT (IC) PACKAGE HAVING A PACKAGE MOLD LAYER BETWEEN A DIE AND A SUBSTRATE COMPRISING TWO TYPES OF RESIN TO IMPROVE COUPLING OF DIE INTERCONNECTS HAVING DIFFERENT SIZES

(71) Applicant: QUALCOMM Incorporated, San Diego, CA (US)

(72) Inventors: Aniket Patil, San Diego, CA (US); Manuel Aldrete, Encinitas, CA (US); Joan Rey Villarba Buot, Escondido, CA (US); Yangyang Sun, San Diego, CA (US)

(21) Appl. No.: 18/999,230

(22) Filed: Dec. 23, 2024

(51) Int. Cl. H01L 23/00; H01L 21/48; H01L 23/498; H01L 23/538; H01L 25/18; H10B 80/00; H10D 80/30

(52) U.S. Cl. CPC H10W 70/095; H10W 70/611; H10W 70/65; H10B 80/00; H10D 80/30; H10W 72/01308; H10W 72/01323; H10W 72/07252; H10W 72/07254; H10W 72/073; H10W 72/07302; H10W 72/07331; H10W 72/221; H10W 72/227; H10W 72/248; H10W 72/354; H10W 72/357; H10W 72/387; H10W 74/15; H10W 90/00; H10W 90/724; H10W 90/734

(57) ABSTRACT

Aspects disclosed an integrated circuit (IC) package having a mold layer between a die and a substrate comprising two types of resin to improve die interconnects having different sizes. The die interconnects include a first set of die interconnects and a second set of die interconnects. The first set of die interconnects are smaller and have a tighter pitch than the second set of die interconnects. A first resin is disposed around each of the first set of die interconnects. A second resin is disposed around each of the second set of die interconnects. These two types of resin enable a die to deploy die interconnects with different sizes which can increase the number of the first set of die interconnects and improve the power transfer over the second set of die interconnects.

### TECHNICAL FIELD

The field of the disclosure relates to design and manufacturing of integrated circuit (IC) packages.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The die(s) is electrically interfaced to metal interconnects (e.g., metal traces) exposed in a top layer of the package substrate. The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes a bottom, outer metallization layer that includes metal interconnects coupled to external metal interconnects (e.g., ball grid array (BGA) interconnects, land grid array (LGA)) to provide an external interface between the die(s) in the IC package. The die(s) may be mounted to the top layer of the package substrate through die interconnects. Other die(s) may also be mounted, utilizing die interconnects, to the bottom, outer metallization layer that includes metal interconnects between BGA interconnects.

### SUMMARY

Aspects disclosed in the detailed description include an integrated circuit (IC) package having a package mold layer between a die and a substrate comprising two types of resin to improve coupling of die interconnects having different sizes. The die interconnects include a first set of die interconnects that carry signals between the die(s) and the substrate and a second set of die interconnects that carry power or are ground connections between the die(s) and the substrate. The die interconnects of the first set of die interconnects are smaller and have a tighter pitch than the second set of die interconnects to address the many signals that are sent between the die(s) and the substrate. A first resin is disposed around each of the first set of die interconnects to suitably fill air gaps between the first set of die interconnects and electrically isolate the individual ones of the first set of die interconnects. The die interconnects of the second set of die interconnects are larger than the die interconnects of the first set to address increased power transfer between the die(s) and the substrate. A second resin is disposed around each of the second set of die interconnects to suitably fill air gaps between the second set of die interconnects and electrically isolate the individual ones of the second set of die interconnects. By utilizing the two types of resin, the die can deploy die interconnects with different sizes which, for a given die footprint, can increase the number of die interconnects of the first set of die interconnects and improve the power transfer over the second set of die interconnects.

In another exemplary aspect, a method of fabricating an IC package having a package mold layer between a die and a substrate comprising two types of resin to improve coupling of die interconnects having different sizes is provided. A first fabrication process includes deploying the first resin as a non-conductive paste prior to attaching the die to the substrate to electrically isolates a first set of die interconnects that are smaller and have a tighter pitch than a second set of die interconnects. A second fabrication process includes deploying the second resin after the die is attached to the substrate through an underfill sub-process to electrically isolate the second set of die interconnects that are larger than the first set of die interconnects and to structurally reinforce the relatively larger solder joints between the second die interconnects and the substrate. To apply the first fabrication process to the larger second set of die interconnects prior to die attachment, portions of the first resin would have a high risk of remaining between the second die interconnects and the substrate after die attachment (also known as entrapment). To apply the second fabrication process to the smaller first set of die interconnects after die attachment, the second resin would not suitably fill the air gaps around the smaller first set of die interconnects. By combining the first and second fabrication processes and applying the first fabrication process to the smaller, first set of die interconnects and the second fabrication process to the larger, second set of die interconnects, the method advantageously leverages the benefits of the two fabrication processes while avoiding their respective disadvantages. In other words, if only one of the fabrication processes is selected for both the first and second sets of die interconnects, the selected fabrication process will dictate that the first and second sets of die interconnects have the same size. If the first fabrication process is solely used, the second set of die interconnects will have to be reduced to the size of the first set of die interconnects which will reduce the power transfer between the substrate and the die. If the second fabrication process is solely used, the size of first set of die interconnects will have to be increased increasing the footprint of the die for a given number of the first set of die interconnects.

In this regard in one aspect, an IC package is disclosed. The IC package comprises a die. The die comprises a plurality of first die interconnects extending in a vertical direction and a plurality of second die interconnects extending in the vertical direction. The IC package also comprises a substrate having a top surface and extending in a horizontal direction. The substrate comprises an outer metallization layer, comprising a first plurality of metal pads coupled to the plurality of first die interconnects in a first region of the top surface and a second plurality of metal pads coupled to the plurality of second die interconnects in a second region of the top surface. The IC package also comprises a package mold layer extending in the horizontal direction and between the substrate and the die. The pack mold layer comprises a first resin surrounding the plurality of first die interconnects and a second resin surrounding the plurality of second die interconnects.

In another aspect, a method for fabricating an IC package is disclosed. The method comprises forming a die. The die comprises a plurality of first die interconnects extending in a vertical direction and a plurality of second die interconnects extending in the vertical direction. The method also comprises forming a substrate having a top surface and extending in a horizontal direction, which comprises forming an outer metallization layer. The outer metallization layer comprises a first plurality of metal pads coupled to the plurality of first die interconnects in a first region of the top surface and a second plurality of metal pads coupled to the plurality of second die interconnects in a second region of the top surface. The method also comprises forming a package mold layer extending in the horizontal direction and between the substrate and the die. The package mold layer comprises a first resin surrounding the plurality of first die interconnects and a second resin surrounding the plurality of second die interconnects.

### BRIEF DESCRIPTION OF THE DRAWINGS

FIG. 1A is a side view of an exemplary integrated circuit (IC) package that includes a package mold layer between a die and a substrate comprising two types of resin to improve coupling of die interconnects having different sizes;

FIG. 1B is a top view of the substrate in the exemplary IC package in FIG. 1A illustrating a barrier separating a first plurality of metal pads and a second plurality of metal pads in FIG. 1A;

FIG. 1C is a side view of an exemplary IC package that includes a package mold layer between a die and a substrate comprising two types of resin to improve coupling of die interconnects having different sizes;

FIG. 2A is a close-up view of the first resin of FIG. 1A surrounding a solder joint between a signal die interconnect and a metal pad of a substrate wherein the signal die interconnect is one of a first plurality of die interconnects in FIGS. 1A-1C, and the metal pad is one of the first plurality of metal pads in FIGS. 1A-1C;

FIG. 2B is a close-up view of the second resin of FIG. 1A surrounding a solder joint between a power delivery network (PDN) die interconnect and a metal pad of a substrate wherein the PDN die interconnect is one of a second plurality of die interconnects in FIGS. 1A-1C and the metal pad is one of the second plurality of metal pads in FIGS. 1A-1C;

FIG. 3A is a side view of the exemplary IC package of FIG. 1A deployed in an exemplary side-by-side configuration;

FIG. 3B is a top view of the exemplary side-by-side configuration in FIG. 3A;

FIG. 4A is a top view of an exemplary side-by-side configuration including another exemplary IC package that includes a package mold layer between a die and a substrate comprising two types of resin to improve coupling of die interconnects having different sizes;

FIG. 4B is a top view of an exemplary side-by-side configuration including another exemplary IC package that includes a package mold layer between a die and a substrate comprising two types of resin to improve coupling of die interconnects having different sizes;

FIG. 4C is a top view of an exemplary side-by-side configuration including another exemplary IC package that includes a package mold layer between a die and a substrate comprising two types of resin to improve coupling of die interconnects having different sizes;

FIG. 5 is a flowchart illustrating an exemplary fabrication process of fabricating an IC package including, but not limited to, the IC packages described in FIGS. 1A-1C, 2A-2B, 3A-3B, and 4A-4C, wherein the IC package includes a package mold layer between a die and a substrate comprising two types of resin to improve coupling of die interconnects having different sizes;

FIG. 6 is a flowchart illustrating another exemplary fabrication process of fabricating an IC package including, but not limited to, the IC packages described in FIGS. 1A-1C, 2A-2B, 3A-3B, and 4A-4C, wherein the IC package includes a package mold layer between a die and a substrate comprising two types of resin to improve coupling of die interconnects having different sizes;

FIGS. 7A-7C are exemplary fabrication stages during fabrication of the IC package according to the fabrication process in FIG. 6;

FIGS. 8A-8E-2 is a flowchart illustrating an exemplary fabrication process of fabricating a substrate of an IC package including, but not limited to, the IC packages described in FIGS. 1A-1C, 2A-2B, 3A-3B, and 4A-4C, wherein the IC package includes a package mold layer between a die and a substrate comprising two types of resin to improve coupling of die interconnects having different sizes;

FIGS. 9A-9L-2 are exemplary fabrication stages during fabrication of the substrate according to the fabrication process in FIGS. 8A-8E-2;

FIG. 10 is a block diagram of an exemplary processor-based system that can include an IC package including a package mold layer between a die and a substrate comprising two types of resin to improve coupling of die interconnects having different sizes, including but not limited to the IC packages in FIGS. 1A-1C, 2A-2B, 3A-3B, and 4A-4C, and fabricated according to the fabrication processes in FIGS. 5, 6, and 8A-8E-2; and

FIG. 11 is a block diagram of an exemplary wireless communications device that includes radio-frequency (RF) components that can include an IC package including a package mold layer between a die and a substrate comprising two types of resin to improve coupling of die interconnects having different sizes, including but not limited to the IC packages in FIGS. 1A-1C, 2A-2B, 3A-3B, and 4A-4C, and fabricated according to the fabrication processes in FIGS. 5, 6, and 8A-8E-2.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

It should be understood that the terms “first,” “second,” “third,” etc., where used herein, are relative terms that may be used to distinguish between similarly named elements and are not meant to limit or imply a strict orientation and/or order unless otherwise specified. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed in the detailed description include an integrated circuit (IC) package having a package mold layer between a die and a substrate comprising two types of resin to improve coupling of die interconnects having different sizes. The die interconnects include a first set of die interconnects that carry signals between the die(s) and the substrate and a second set of die interconnects that carry power or are ground connections between the die(s) and the substrate. The die interconnects of the first set of die interconnects are smaller and have a tighter pitch than the second set of die interconnects to address the many signals that are sent between the die(s) and the substrate. A first resin is disposed around each of the first set of die interconnects to suitably fill air gaps between the first set of die interconnects and electrically isolate the individual ones of the first set of die interconnects. The die interconnects of the second set of die interconnects are larger than the die interconnects of the first set to address increased power transfer between the die(s) and the substrate. A second resin is disposed around each of the second set of die interconnects to suitably fill air gaps between the second set of die interconnects and electrically isolate the individual ones of the second set of die interconnects. By utilizing the two types of resin, the die can deploy die interconnects with different sizes which, for a fixed die footprint, can increase the number of die interconnects of the first set of die interconnects and improve the power transfer over the second set of die interconnects.

In another exemplary aspect, a method of fabricating an IC package having a package mold layer between a die and a substrate comprising two types of resin to improve coupling of die interconnects having different sizes is provided. A first fabrication process includes deploying the first resin as a non-conductive paste prior to attaching the die to the substrate to electrically isolates a first set of die interconnects that are smaller and have a tighter pitch than a second set of die interconnects. A second fabrication process includes deploying the second resin after the die is attached to the substrate through an underfill sub-process to electrically isolate the second set of die interconnects that are larger than the first set of die interconnects and to structurally reinforce the relatively larger solder joints between the second die interconnects and the substrate. To apply the first fabrication process to the larger second set of die interconnects prior to die attachment, portions of the first resin would have a high risk of remaining between the second die interconnects and the substrate after die attachment (also known as entrapment). To apply the second fabrication process to the smaller first set of die interconnects after die attachment, the second resin would not suitably fill the air gaps around the smaller first set of die interconnects. By combining the first and second fabrication processes and applying the first fabrication process to the smaller, first set of die interconnects and the second fabrication process to the larger, second set of die interconnects, the method advantageously leverages the benefits of the two fabrication processes while avoiding their respective disadvantages. In other words, if only one of the fabrication processes is selected for both the first and second sets of die interconnects, the selected fabrication process will dictate that the first and second sets of die interconnects have the same size. If the first fabrication process is solely used, the second set of die interconnects will have to be reduced to the size of the first set of die interconnects which will reduce the power transfer between the substrate and the die. If the second fabrication process is solely used, the size of first set of die interconnects will have to be increased increasing the footprint of the die for a given number of the first set of die interconnects.

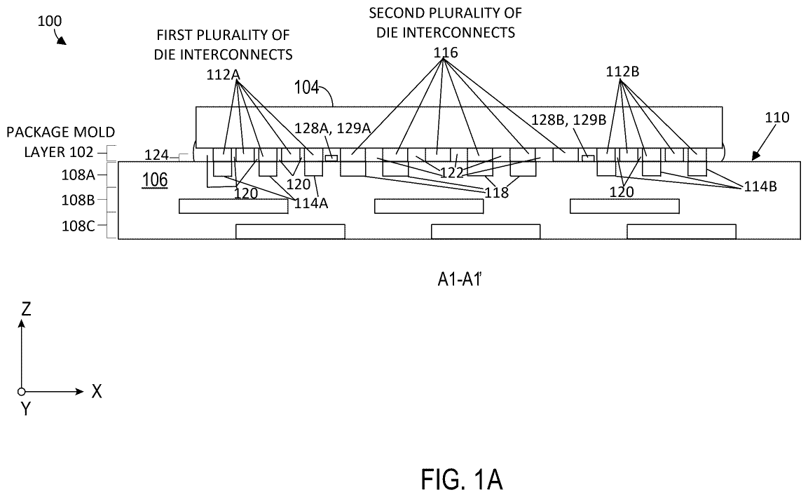

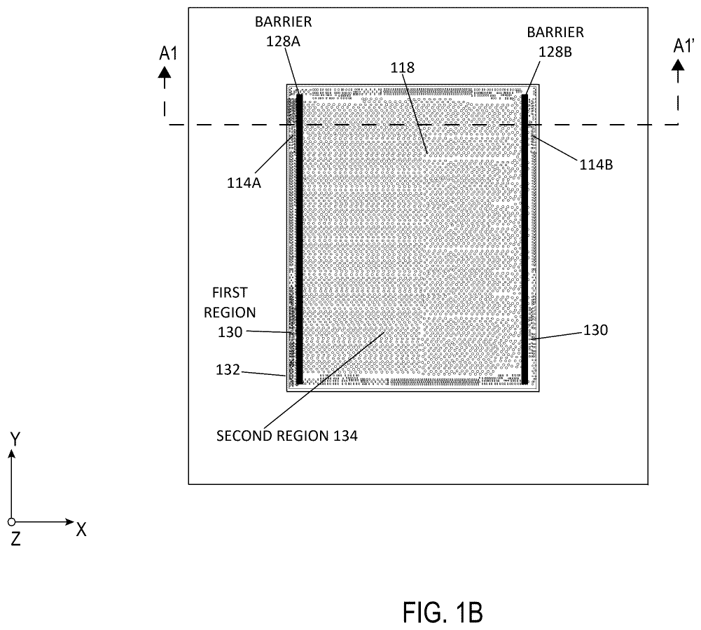

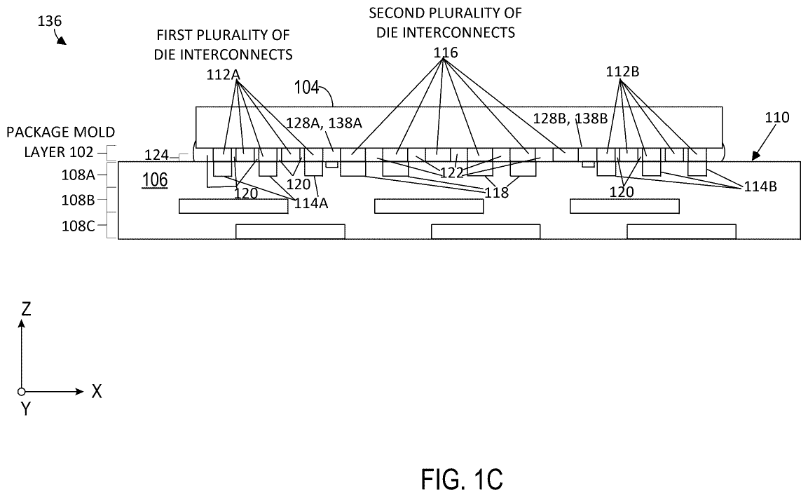

In this regard, FIG. 1A is a side view of an exemplary IC package 100 that includes a package mold layer 102 between a die 104 and a substrate 106 comprising two types of resin to improve coupling of die interconnects having different sizes. The IC package 100 includes the substrate 106 extending in a horizontal direction (X-, Y-axes direction) and the die 104 coupled to the top, in a vertical direction (Z-axis direction), of the substrate 106. The substrate 106 commonly routes signals and power between the die 104 and the substrate 106 and a printed circuit board (PCB) (not shown).

In this example, the package substrate 106 includes metallization layers 108A-108C including a first, upper metallization layer 108A and a bottom, outer metallization layer 108C. The substrate 106 has a top surface 110 having a first region (not shown) and a second region (not shown). The die 104 includes a first plurality of die interconnects 112A-112B (e.g., raised metal bumps, pillars) extending in the vertical direction (Z-axis direction) that are electrically coupled to metal interconnects including metal pads 114A-114B in the first region (not shown) in the upper, outer metallization layer 108A. The first plurality of die interconnects 112A-112B are suitable for carrying signals between the die 104 and the substrate 106. The pitch of the first plurality of die interconnects 112A-112B is at least 70 micrometers (μm). The die 104 includes a second plurality of die interconnects 116 (e.g., raised metal bumps, pillars) extending in the vertical direction (Z-axis direction) that are electrically coupled to metal interconnects including metal pads 118 in the second region (not shown) in the upper, outer metallization layer 108A. The second plurality of die interconnects 116 are suitable for carrying power and ground and may be referred collectively as a power delivery network (PDN). The pitch of the second plurality of die interconnects 116 is at least 98 μm.

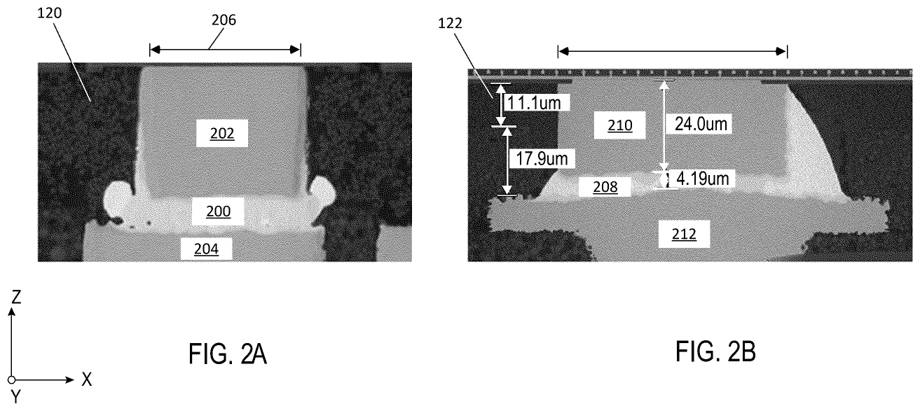

The package mold layer 102 extends in the horizontal direction (X-, Y-axes direction) and between the substrate 106 and the die 104. The first plurality of die interconnects 112A-112B have a first diameter (see FIG. 2A). The second plurality of die interconnects 116 have a second diameter (see FIG. 2B). The second diameter is smaller than the first diameter. The ratio between the second diameter and the first diameter is between 1.7 and 2.5.

The package mold layer 102 includes a first resin 120 surrounding the first plurality of die interconnects 112A-112B. The package mold layer 102 includes a second resin 122 surrounding the second plurality of die interconnects 116. The first resin 120 is an anhydride-based resin. The second resin 122 is an amine-based resin.

The substrate 106 includes an outer solder resist layer 124 on the top surface 110 of the substrate 106. The substrate 106 also includes a barrier 128A-128B between the first plurality of metal pads 114A-114B and the second plurality of metal pads 118. The barriers 128A-128B as shown in FIG. 1A are above the top surface 110 and are referred to as dams 129A-129B which block the first resin 120 during fabrication from spilling into the second region of the top surface 110 where the second plurality of die interconnects 116 attach to the substrate 106.

FIG. 1B is a top view of the substrate 106 in the exemplary IC package 100 in FIG. 1A illustrating the barrier 128A-128B separating the first plurality of metal pads 114A-114B and the second plurality of metal pads 118 in FIG. 1A. A first region 130 on the top surface 110 of the substrate 106 as described above is defined between each of the barriers 128A-128B and the outer perimeter of the die footprint 132. A second region 134 on the top surface 110 of the substrate 106 as described above is defined between the barriers 128A-128B.

FIG. 1C is a side view of an exemplary IC package 136 that includes a package mold layer between a die and a substrate comprising two types of resin to improve coupling of die interconnects having different sizes. Common elements between the IC package 100 in FIG. 1A and the IC package 136 in FIG. 1C are shown with common element numbers. The barriers 128A-128B are below the top surface 110 of the substrate 106 and are trenches 138A-138B which collect any overflow of the first resin 120 during fabrication from spreading into the second region 134 of the top surface 110 where the second plurality of die interconnects 116 attach to the substrate 106.

FIG. 2A is a close-up view of the first resin 120 of FIG. 1A surrounding a solder joint 200 between a signal die interconnect 202 and a metal pad 204 of a substrate 106 wherein the signal die interconnect 202 is one of the first plurality of die interconnects 112A in FIGS. 1A-1C and the metal pad 204 is one of the first plurality of metal pads 114A in FIGS. 1A-1C. The signal die interconnect 202 is a copper pillar and has a diameter 206 between 32-35 μm. The minimum pitch between the signal die interconnect 202 and the closest die interconnect in the first plurality of die interconnects 112A is at least 70 μm.

FIG. 2B is a close-up view of the second resin 122 of FIG. 1A surrounding a solder joint 208 between a PDN die interconnect 210 and a metal pad 212 of a substrate 106 wherein the PDN die interconnect 210 is one of the second plurality of die interconnects 116 in FIGS. 1A-1C and the metal pad 212 is one of the second plurality of metal pads 118 in FIGS. 1A-1C.

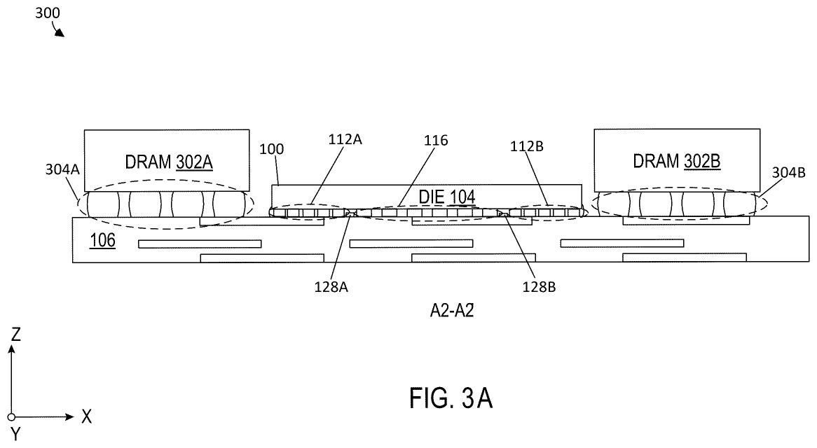

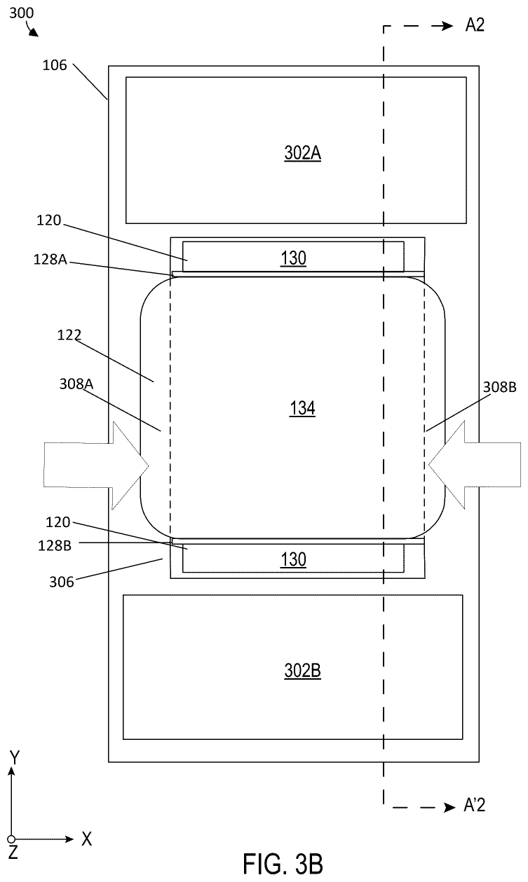

FIG. 3A is a side view of the exemplary IC package 100 of FIG. 1A deployed in an exemplary side-by-side configuration 300. The side-by-side configuration 300 includes dynamic random access memory (DRAM) 302A-302B coupled to the substrate 106 through die interconnects 304A-304B, respectively. The use of the first resin 120 between the first plurality of die interconnects 112A-112B enables the first plurality of die interconnects 112A-112B to be smaller than the second plurality of die interconnects 116. As a result, for a given die footprint, the number of the first plurality of die interconnects 112A-112B may be increased. Alternatively, the footprint of a die such as the die 104, may be decreased for a given number of the first plurality of die interconnects 112A-112B enabling the DRAMs 302A-302B to be closer in proximity in the horizontal direction (X-axis direction) to allow shorter conductivity paths between the die 104 and the DRAMs 302A-302B.

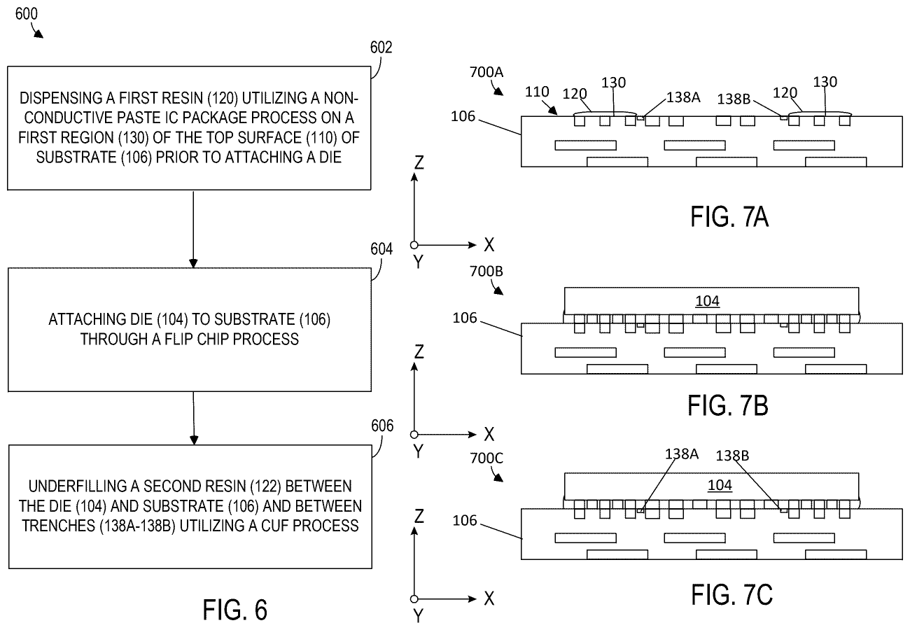

FIG. 3B is a top view of the exemplary side-by-side configuration 300 in FIG. 3A. A die footprint 306 outlines the perimeter of die 104. The first region 130 of the substrate 106 includes the first resin 120. The second region 134 of the substrate 106 includes the second resin 122. As will be described in FIGS. 6 and 7A-7C, the first resin 120 is a non-conductive paste deposited on the substrate 106 prior to attaching the die 104 to the substrate 106, and the second resin 122 is an adhesive or epoxy material utilizing a capability underfill (CUF) process after attaching the die 104 to the substrate 106. The second resin 122 would be dispensed from either the left side 308A or the right side 308B of the die 104 between the barriers 128A and 128B.

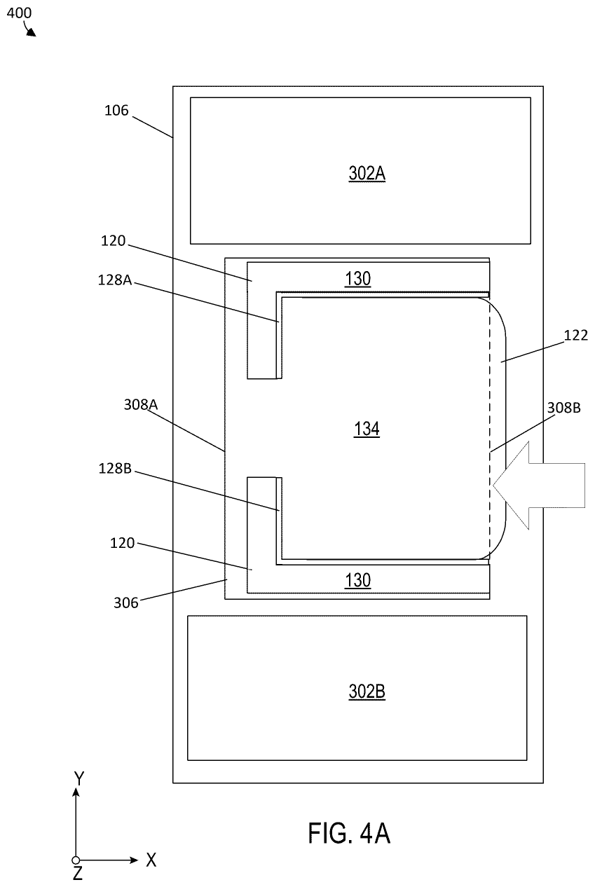

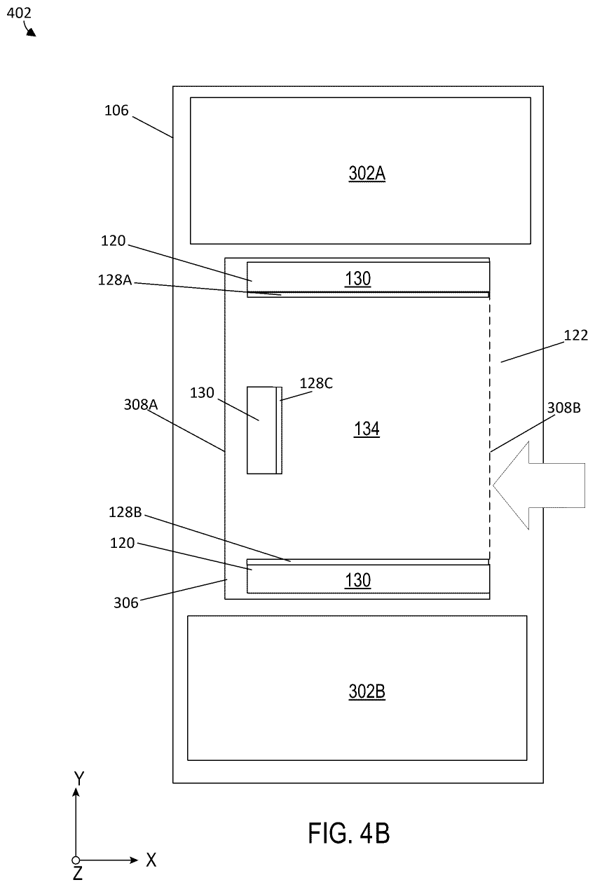

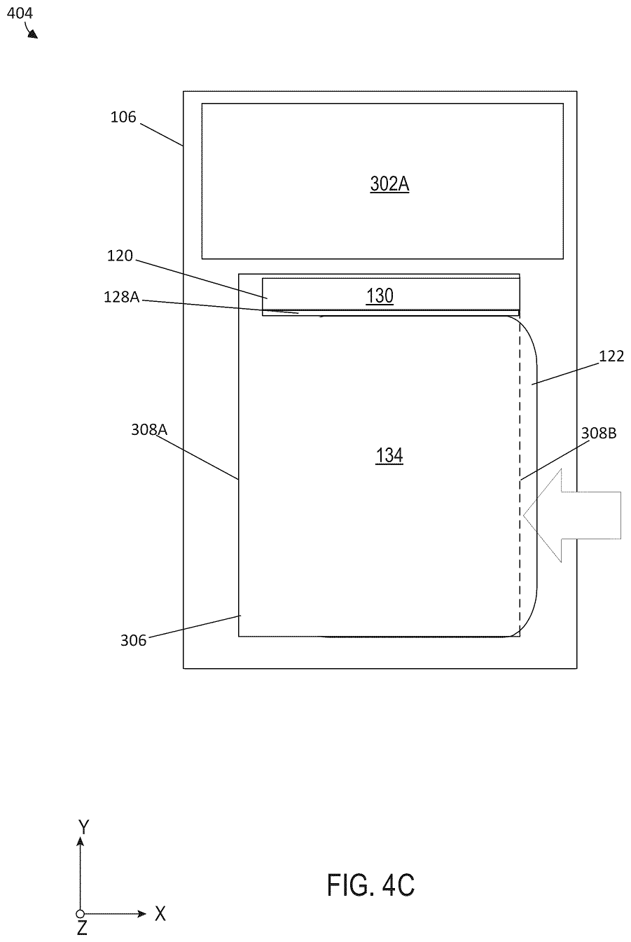

FIG. 4A is a top view of an exemplary side-by-side configuration including another exemplary IC package 400 that includes a package mold layer between a die and a substrate comprising two types of resin to improve coupling of die interconnects having different sizes. Common elements between the IC package 300 in FIGS. 3A-3B and the IC package 400 in FIG. 4A are shown with common element numbers. The first region 130 of the substrate 106 comprises two “L” shapes facing each other and includes the first resin 120 surrounding the first plurality of die interconnects 112A (not shown). The second region 134 of the substrate 106 includes the second resin 122 surrounding the second plurality of die interconnects 116 (not shown). As will be described in FIGS. 6 and 7A-7C, the first resin 120 is a non-conductive paste deposited on the substrate 106 prior to attaching the die 104 to the substrate 106, and the second resin 122 is an adhesive or epoxy material utilizing a CUF process after attaching the die 104 to the substrate 106. The second resin 122 would be dispensed from the right side 308B of the die 104 between the barriers 128A and 128B which is opposite the bases of the two “L” shapes of the first region 130.

FIG. 4B is a top view of an exemplary side-by-side configuration including another exemplary IC package 402 that includes a package mold layer between a die and a substrate comprising two types of resin to improve coupling of die interconnects having different sizes. Common elements between the IC package 300 in FIGS. 3A-3B and the IC package 402 in FIG. 4B are shown with common element numbers. The first region 130 of the substrate 106 comprises three bars, two of which face each other and a third bar orthogonal to the two facing each other. Adjacent to the first region 130 towards the inner area of the die 104 are the barriers 128A-128C. The first region 130 includes the first resin 120 surrounding the first plurality of die interconnects 112A (not shown). The second region 134 of the substrate 106 includes the second resin 122 surrounding the second plurality of die interconnects 116 (not shown). As will be described in FIGS. 6 and 7A-7C, the first resin 120 is a non-conductive paste deposited on the substrate 106 prior to attaching the die 104 to the substrate 106, and the second resin 122 is an adhesive or epoxy material utilizing a CUF process after attaching the die 104 to the substrate 106. The second resin 122 would be dispensed from the right side 308B of the die 104 between the barriers 128A and 128B which is opposite a barrier 128C.

FIG. 4C is a top view of an exemplary side-by-side configuration including another exemplary IC package 404 that includes a package mold layer between a die and a substrate comprising two types of resin to improve coupling of die interconnects having different sizes. Common elements between the IC package 300 in FIGS. 3A-3B and the IC package 404 in FIG. 4B are shown with common element numbers. The IC package 404 contains the DRAM 302A but not the DRAM 302B. As such, the first region 130 of the substrate 106 comprises one bar adjacent to the DRAM 302A. Adjacent to the first region 130 towards the inner area of the die 104 is the barrier 128A. The first region 130 includes the first resin 120 surrounding the first plurality of die interconnects 112A (not shown). The second region 134 of the substrate 106 includes the second resin 122 surrounding the second plurality of die interconnects 116 (not shown). As will be described in FIGS. 6 and 7A-7C, the first resin 120 is a non-conductive paste deposited on the substrate 106 prior to attaching the die 104 to the substrate 106, and the second resin 122 is an adhesive or epoxy material utilizing a CUF process after attaching the die 104 to the substrate 106. The second resin 122 would be dispensed from either the right side 308B or the left side 308A of the die 104 below the barrier 128A.

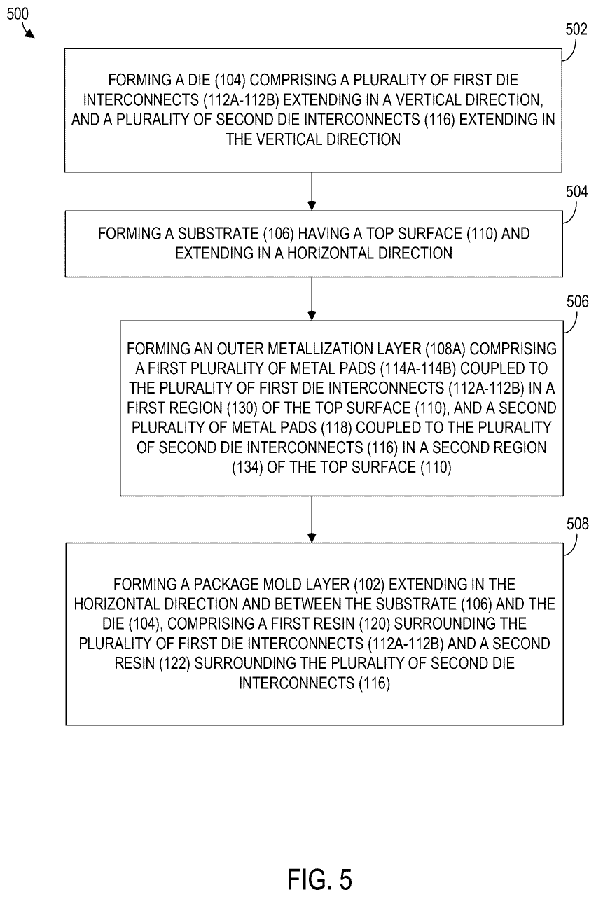

An electronic device including, but not limited to, an IC package, such as the IC packages 100, 300, 400, 402 and 404, which includes a package mold layer between a die and a substrate comprising two types of resin to improve coupling of die interconnects having different sizes and can be fabricated by different fabrication processes. FIG. 5 is a flowchart illustrating an exemplary fabrication process 500 of fabricating an IC package including, but not limited to, the IC packages described in FIGS. 1A-1C, 2A-2B, 3A-3B, and 4A-4C, wherein the IC package includes a package mold layer between a die and a substrate comprising two types of resin to improve coupling of die interconnects having different sizes.

In this regard, a first exemplary step in the fabrication process 500 of FIG. 5 can include forming a die 104 comprising a plurality of first die interconnects 112A-112B extending in a vertical direction, and a plurality of second die interconnects 116 extending in the vertical direction (block 502). A next step in the fabrication process 500 can include forming a substrate 106 having a top surface 110 and extending in a horizontal direction (block 504). Forming the substrate 106 of the fabrication process 500 includes forming an outer metallization layer 108A comprising a first plurality of metal pads 114A-114B coupled to the plurality of first die interconnects 112A-112B in a first region 130 of the top surface 110, and a second plurality of metal pads 118 coupled to the plurality of second die interconnects 116 in a second region 134 of the top surface 110 (block 506). A next step in the fabrication process 500 can include forming a package mold layer 102 extending in the horizontal direction and between the substrate 106 and the die 104, comprising a first resin 120 surrounding the plurality of first die interconnects 112A-112B and a second resin 122 surrounding the plurality of second die interconnects 116 (block 508).

Other fabrication processes can also be employed to fabricate an IC package including, but not limited to, the IC packages described in FIGS. 1A-1C, 2A-2B, 3A-3B, and 4A-4C, wherein the IC package includes a package mold layer between a die and a substrate comprising two types of resin to improve coupling of die interconnects having different sizes. In this regard, FIG. 6 is a flowchart illustrating another exemplary fabrication process 600 of fabricating an IC package including, but not limited to, the IC packages described in FIGS. 1A-1C, 2A-2B, 3A-3B, and 4A-4C, wherein the IC package includes a package mold layer between a die and a substrate comprising two types of resin to improve coupling of die interconnects having different sizes. FIGS. 7A-7C are exemplary fabrication stages during fabrication of the IC package according to the fabrication process 600 in FIG. 6. For convenience, the fabrication process 600 will be described in connection with the substrate 106 comprising etched out trenches 138A-138B as shown in FIG. 1C but is applicable to the IC packages 100, 300, 400, 402, and 404.

In this regard, as shown in fabrication stage 700A in FIG. 7A, an exemplary step in the fabrication process 600 is dispensing a first resin 120 utilizing a non-conductive paste IC package process on a first region 130 of the top surface 110 of the substrate 106 prior to attaching a die 104 (block 602). As shown at fabrication stage 700B in FIG. 7B, a next step in the fabrication process 600 can include attaching the die 104 to the substrate 106 through a flip chip process (block 604). As shown at fabrication stage 700C in FIG. 7C, a next step in the fabrication process 600 can include underfilling a second resin 122 between the die 104 and the substrate 106 and between the trenches 138A-138B utilizing a CUF process (block 606).

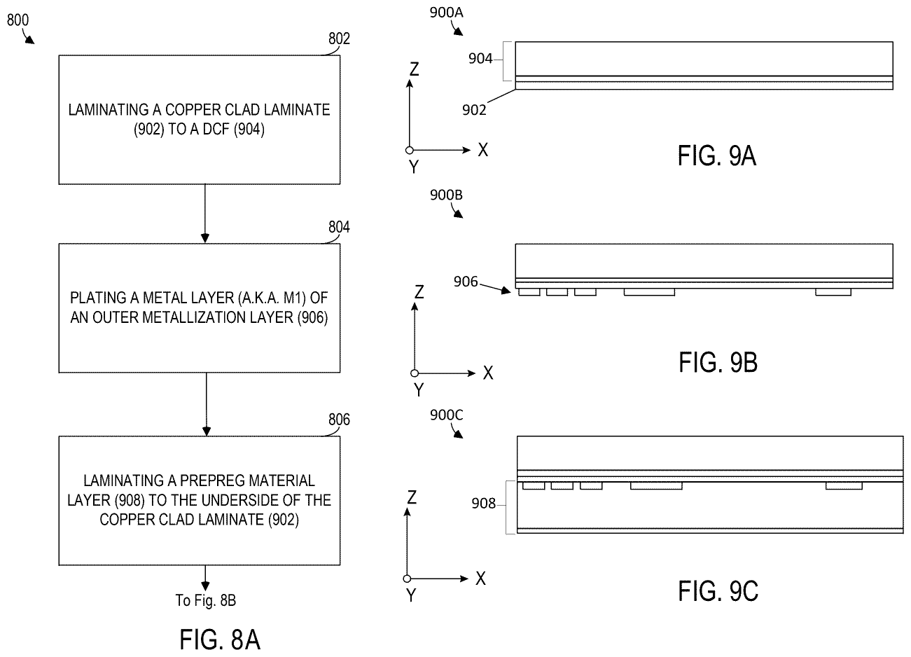

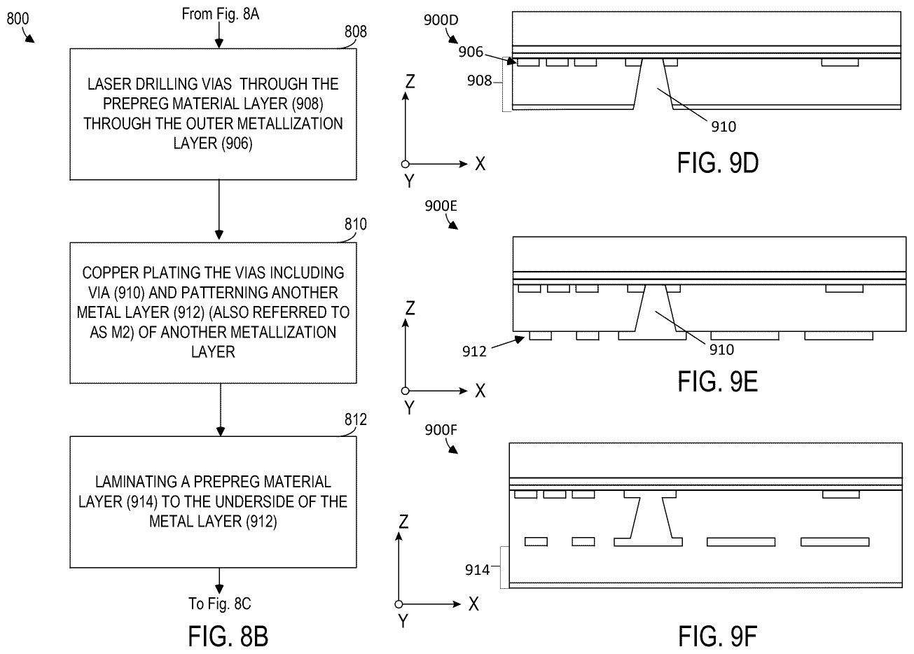

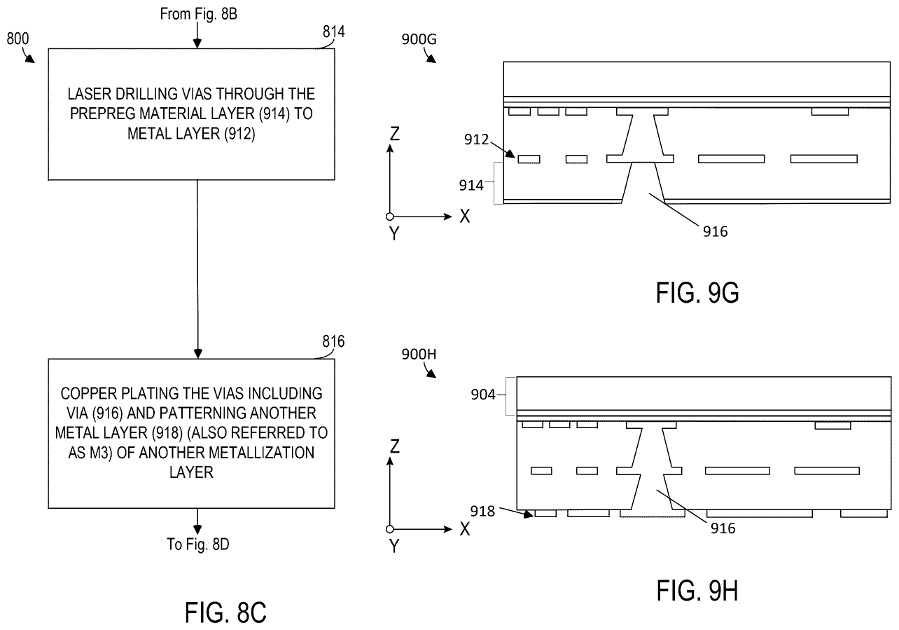

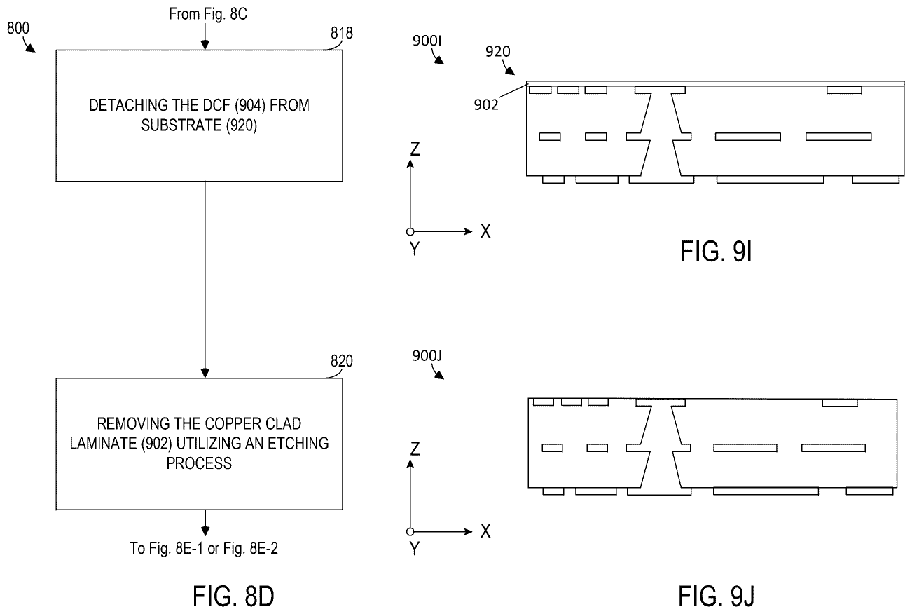

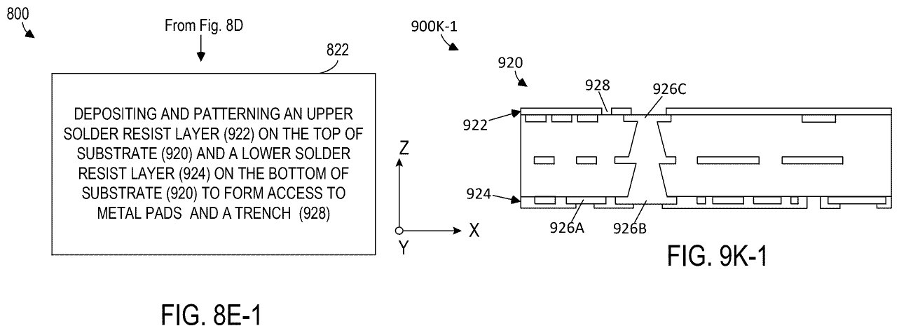

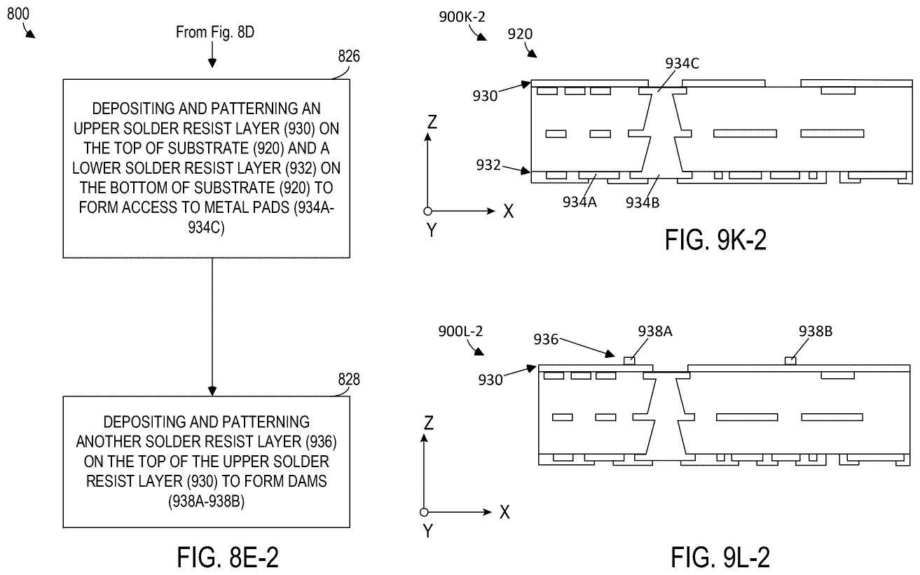

FIGS. 8A-8E-2 is a flowchart illustrating an exemplary fabrication process 800 of fabricating a substrate of an IC package including, but not limited to, the IC packages described in FIGS. 1A-1C, 2A-2B, 3A-3B, and 4A-4C, wherein the IC package includes a package mold layer between a die and a substrate comprising two types of resin to improve coupling of die interconnects having different sizes. FIGS. 9A-9L-2 are exemplary fabrication stages during fabrication of the substrate according to the fabrication process in FIGS. 8A-8E-2.

In this regard, as shown in assembly stage 900A in FIG. 9A, an exemplary step in the fabrication process 800 is laminating a copper clad laminate 902 to a detach core with foil (DCF) 904 (block 802 in FIG. 8A). The DCF 904 acts as a carrier for fabricating a substrate. As shown at assembly stage 900B in FIG. 9B, a next step in the fabrication process 800 can include plating a metal layer (also referred to as M1) of an outer metallization layer 906 such as the outer metallization layer 108A (block 804 in FIG. 8A). As shown at assembly stage 900C in FIG. 9C, a next step in the fabrication process 800 can include laminating a prepreg material layer 908 to the underside of the copper clad laminate 902 (block 806 in FIG. 8A). The prepreg material layer 908 is a dielectric layer which includes a glass weave at its core.

As shown at assembly stage 900D in FIG. 9D, a next step in the fabrication process 800 can include laser drilling vias including a via 910 through the prepreg material layer 908 through the outer metallization layer 906 (block 808 in FIG. 8B). As shown at assembly stage 900E in FIG. 9E, a next step in the fabrication process 800 can include copper plating the vias including the via 910 and patterning another metal layer 912 (also referred to as M2) of another metallization layer such as the metallization layer 108B (block 810 in FIG. 8B). As shown at assembly stage 900F in FIG. 9F, a next step in the fabrication process 800 can include laminating a prepreg material layer 914 to the underside of the metal layer 912 (block 812 in FIG. 8B). As shown at assembly stage 900G in FIG. 9G, a next step in the fabrication process 800 can include laser drilling vias including a via 916 through the prepreg material layer 914 to the metal layer 912 (block 814 in FIG. 8C). As shown at assembly stage 900H in FIG. 9H, a next step in the fabrication process 800 can include copper plating the vias including the via 916 and patterning another metal layer 918 (also referred to as M3) of another metallization layer such as the metallization layer 108C (block 816 in FIG. 8C). As shown at assembly stage 900I in FIG. 9I, a next step in the fabrication process 800 can include detaching the DCF 904 from a substrate 920 (block 818 in FIG. 8D). As shown at assembly stage 900J in FIG. 9J, a next step in the fabrication process 800 can include removing the copper clad laminate 902 utilizing an etching process (block 820 in FIG. 8C). The next steps in the fabrication process 800 may follow one of two paths depending on whether a barrier such as the barriers 128A-128B is a dam such as the dams 129A-129B or a trench such as the trenches 138A-138B. One path which comprises blocks 822-824 is for fabricating a trench such as the trenches 138A-138B. The other path which comprises blocks 826-828 is for fabricating a dam such as the dams 129A-129B.

As shown at assembly stage 900K-1 in FIG. 9K-1, a next step in the fabrication process 800 can include depositing and patterning an upper solder resist layer 922 on the top of the substrate 920 and a lower solder resist layer 924 on the bottom of the substrate 920 to form access to metal pads 926A-926C and a trench 928 (block 822 in FIG. 8E-1). As shown at assembly stage 900L-2 in FIG. 9L-1, a next step in the fabrication process 800 can include (block 824 in FIG. 8E-1).

As shown at assembly stage 900K-2 in FIG. 9K-2, a next step in the fabrication process 800 can include depositing and patterning an upper solder resist layer 930 on the top of the substrate 920 and a lower solder resist layer 932 on the bottom of the substrate 920 to form access to metal pads 934A-934C (block 826 in FIG. 8E-2). As shown at assembly stage 900L-2 in FIG. 9L-2, a next step in the fabrication process 800 can include depositing and patterning another solder resist layer 936 on the top of the upper solder resist layer 930 to form dams 938A-938B (block 828 in FIG. 8E-2).

Electronic devices that include an IC package, wherein the IC package is fabricated according to the fabrication process in FIGS. 5, 6, and 8A-8E-2, wherein the IC package including, but not limited to, the IC packages described in FIGS. 1A-1C, 2A-2B, 3A-3B, and 4A-4C includes a package mold layer between a die and a substrate comprising two types of resin to improve coupling of die interconnects having different sizes, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

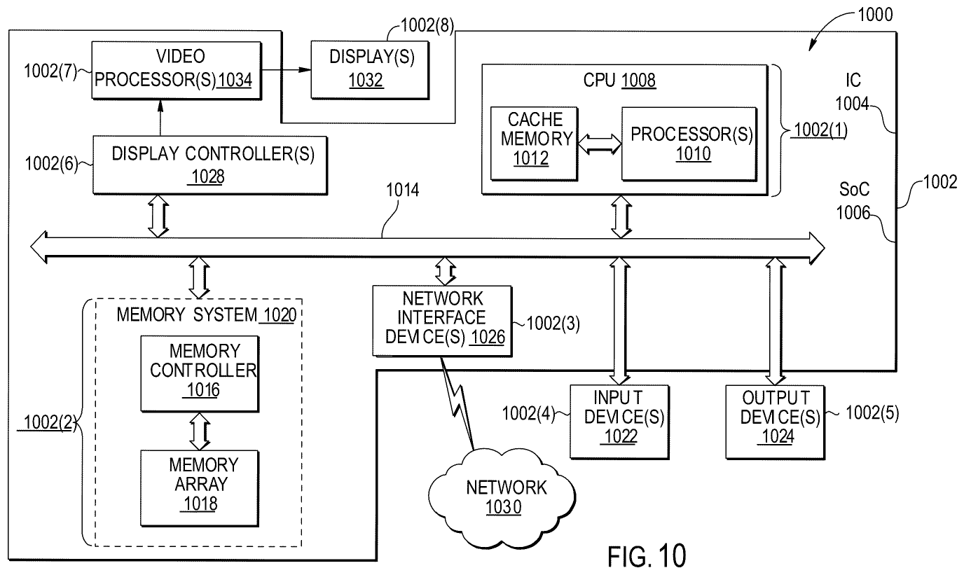

In this regard, FIG. 10 is a block diagram of an exemplary processor-based system 1000 that can include an IC package including a package mold layer between a die and a substrate comprising two types of resin to improve coupling of die interconnects having different sizes, including but not limited to the IC packages in FIGS. 1A-1C, 2A-2B, 3A-3B, and 4A-4C, and fabricated according to the fabrication processes in FIGS. 5, 6, and 8A-8E-2, and according to any exemplary aspects disclosed herein. In this example, the processor-based system 1000 may be assembled into one electronic device 1002 including an IC package(s) such as the IC packages 100, 136, 300, 400, 402, and 404 including a package mold layer between a die and a substrate comprising two types of resin to improve coupling of die interconnects having different sizes. The processor-based system 1000 includes a central processing unit (CPU) 1008 that includes one or more processors 1010, which may also be referred to as CPU cores or processor cores. The CPU 1008 may have cache memory 1012 coupled to the CPU 1008 for rapid access to temporarily stored data. The CPU 1008 may be part of the electronic device 1002 or may be a different electronic device 1002(1). The CPU 1008 is coupled to a system bus 1014 and can intercouple client and server devices included in the processor-based system 1000. As is well known, the CPU 1008 communicates with these other devices by exchanging address, control, and data information over the system bus 1014. For example, the CPU 1008 can communicate bus transaction requests to a memory controller 1016, as an example of a slave device. Although not illustrated in FIG. 10, multiple system buses 1014 could be provided, wherein each system bus 1014 constitutes a different fabric.

Other client and server devices can be connected to the system bus 1014. As illustrated in FIG. 10, these devices can include a memory system 1020 that includes the memory controller 1016 and a memory array(s) 1018, one or more input devices 1022, one or more output devices 1024, one or more network interface devices 1026, and one or more display controllers 1028, as examples. Each of the memory system(s) 1020, the one or more input devices 1022, the one or more output devices 1024, the one or more network interface devices 1026, and the one or more display controllers 1028 can be provided in the same electronic device 1002 or different electronic devices 1002(2)-1002(6). The input device(s) 1022 can include any type of input device, including, but not limited to, input keys, switches, voice processors, etc. The output device(s) 1024 can include any type of output device, including, but not limited to, audio, video, other visual indicators, etc. The network interface device(s) 1026 can be any device configured to allow exchange of data to and from a network 1030. The network 1030 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1026 can be configured to support any type of communications protocol desired.

The CPU 1008 may also be configured to access the display controller(s) 1028 over the system bus 1014 to control information sent to one or more displays 1032. The display controller(s) 1028 sends information to the display(s) 1032 to be displayed via one or more video processor(s) 1034, which process the information to be displayed into a format suitable for the display(s) 1032. The display controller(s) 1028 and video processor(s) 1034 can be included as ICs in the same electronic device 1002 or different electronic devices 1002(6)-1002(7), and in the same or different electronic devices containing the CPU 1008, as an example. The display(s) 1032 can be provided as an electronic device 1002(8) and can include any type of display, including, but not limited to, a cathode ray tube (CRT), a liquid crystal display (LCD), a plasma display, a light emitting diode (LED) display, etc.

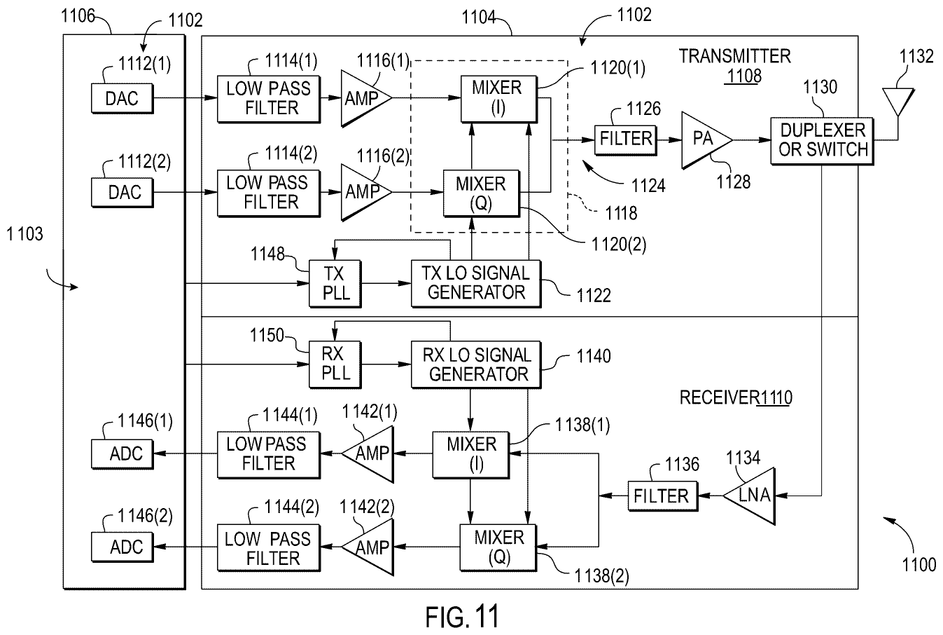

FIG. 11 is a block diagram of an exemplary wireless communications device 1100 that includes radio-frequency (RF) components that can include an IC package including a package mold layer between a die and a substrate comprising two types of resin to improve coupling of die interconnects having different sizes, including but not limited to the IC packages in FIGS. 1A-1C, 2A-2B, 3A-3B, and 4A-4C, and fabricated according to the fabrication processes in FIGS. 5, 6, and 8A-8E-2, and according to any exemplary aspects disclosed herein. The wireless communications device 1100 may include or be provided in any of the above-referenced devices, as examples. As shown in FIG. 11, the wireless communications device 1100 includes a transceiver 1104 and a data processor 1106. The data processor 1106 may include a memory to store data and program codes. The transceiver 1104 includes a transmitter 1108 and a receiver 1110 that support bi-directional communications. In general, the wireless communications device 1100 may include any number of transmitters 1108 and/or receivers 1110 for any number of communication systems and frequency bands. All or a portion of the transceiver 1104 may be implemented on one or more analog ICs, RF ICs (RFICs), mixed-signal ICs, etc.

The transmitter 1108 or the receiver 1110 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1110. In the direct-conversion architecture, a signal is frequency-converted between RF and baseband in one stage. The super-heterodyne and direct-conversion architectures may use different circuit blocks and/or have different requirements. In the wireless communications device 1100 in FIG. 11, the transmitter 1108 and the receiver 1110 are implemented with the direct-conversion architecture.

In the transmit path, the data processor 1106 processes data to be transmitted and provides I and Q analog output signals to the transmitter 1108. In the exemplary wireless communications device 1100, the data processor 1106 includes digital-to-analog converters (DACs) 1112(1), 1112(2) for converting digital signals generated by the data processor 1106 into the I and Q analog output signals (e.g., I and Q output currents) for further processing.

Within the transmitter 1108, lowpass filters 1114(1), 1114(2) filter the I and Q analog output signals, respectively, to remove undesired signals caused by the prior digital-to-analog conversion. Amplifiers (AMPs) 1116(1), 1116(2) amplify the signals from the lowpass filters 1114(1), 1114(2), respectively, and provide I and Q baseband signals. An upconverter 1118 upconverts the I and Q baseband signals with I and Q transmit (TX) local oscillator (LO) signals through mixers 1120(1), 1120(2) from a TX LO signal generator 1122 to provide an upconverted signal 1124. A filter 1126 filters the upconverted signal 1124 to remove undesired signals caused by the frequency up-conversion as well as noise in a receive frequency band. A power amplifier (PA) 1128 amplifies the upconverted signal 1124 from the filter 1126 to obtain the desired output power level and provides a transmit RF signal. The transmit RF signal is routed through a duplexer or switch 1130 and transmitted via an antenna 1132.

In the receive path, the antenna 1132 receives signals transmitted by base stations and provides a received RF signal, which is routed through the duplexer or switch 1130 and provided to a low noise amplifier (LNA) 1134. The duplexer or switch 1130 is designed to operate with a specific receive (RX)-to-TX duplexer frequency separation, such that RX signals are isolated from TX signals. The received RF signal is amplified by the LNA 1134 and filtered by a filter 1136 to obtain a desired RF input signal. Down-conversion mixers 1138(1), 1138(2) mix the output of the filter 1136 with I and Q RX LO signals (i.e., LO_I and LO_Q) from an RX LO signal generator 1140 to generate I and Q baseband signals. The I and Q baseband signals are amplified by AMPs 1142(1), 1142(2) and further filtered by lowpass filters 1144(1), 1144(2) to obtain I and Q analog input signals, which are provided to the data processor 1106. In this example, the data processor 1106 includes analog-to-digital converters (ADCs) 1146(1), 1146(2) for converting the analog input signals into digital signals to be further processed by the data processor 1106.

In the wireless communications device 1100 of FIG. 11, the TX LO signal generator 1122 generates the I and Q TX LO signals used for frequency up-conversion, while the RX LO signal generator 1140 generates the I and Q RX LO signals used for frequency down-conversion. Each LO signal is a periodic signal with a particular fundamental frequency. A TX phase-locked loop (PLL) circuit 1148 receives timing information from the data processor 1106 and generates a control signal used to adjust the frequency and/or phase of the TX LO signals from the TX LO signal generator 1122. Similarly, an RX PLL circuit 1150 receives timing information from the data processor 1106 and generates a control signal used to adjust the frequency and/or phase of the RX LO signals from the RX LO signal generator 1140.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC) package, comprising:
   a die, comprising:
      a plurality of first die interconnects extending in a vertical direction; and
      a plurality of second die interconnects extending in the vertical direction;
   a substrate having a top surface and extending in a horizontal direction, the substrate comprising an outer metallization layer, comprising:
      a first plurality of metal pads coupled to the plurality of first die interconnects in a first region of the top surface; and
      a second plurality of metal pads coupled to the plurality of second die interconnects in a second region of the top surface; and
   a package mold layer extending in the horizontal direction and between the substrate and the die, comprising:
      a first resin surrounding the plurality of first die interconnects; and
      a second resin surrounding the plurality of second die interconnects.
2. The IC package of clause 1, wherein:
   the plurality of first die interconnects have a first diameter; and
   the plurality of second die interconnects have a second diameter, the second diameter greater than the first diameter.
3. The IC package of clause 2, wherein a ratio between the second diameter and the first diameter is between 1.7 and 2.5.
4. The IC package of any of clauses 1-3, wherein:
   the first resin is an anhydride-based resin; and
   the second resin is an amine-based resin.
5. The IC package of any of clauses 1-4, wherein the substrate further comprises:
   an outer solder resist layer on the top surface of the substrate; and
   a barrier between the first plurality of metal pads and the second plurality of metal pads.
6. The IC package of claim 5, wherein the barrier is a trench etched into the outer solder resist layer, the trench being filled by any excess of either the first resin, the second resin, or both.
7. The IC package of clause 5, wherein the barrier is a dam adjacent to the outer solder resist layer.
8. The IC package of any of clauses 1-7 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.
9. A method of fabricating an integrated circuit (IC) package, comprising:
   forming a die, comprising:
      a plurality of first die interconnects extending in a vertical direction; and
      a plurality of second die interconnects extending in the vertical direction;
   forming a substrate having a top surface and extending in a horizontal direction, comprising:
      forming an outer metallization layer, comprising:
         a first plurality of metal pads coupled to the plurality of first die interconnects in a first region of the top surface; and
         a second plurality of metal pads coupled to the plurality of second die interconnects in a second region of the top surface; and
   forming a package mold layer extending in the horizontal direction and between the substrate and the die, comprising:
      a first resin surrounding the plurality of first die interconnects; and
      a second resin surrounding the plurality of second die interconnects.
10. The method of clause 9, wherein:
   the plurality of first die interconnects have a first diameter; and
   the plurality of second die interconnects have a second diameter, the second diameter greater than the first diameter.
11. The method of clause 10, wherein a ratio between the second diameter and the first diameter is between 1.7 and 2.5.
12. The method of any of clauses 9-11, wherein:
   the first resin is an anhydride-based resin; and
   the second resin is an amine-based resin.
13. The method of any of clauses 9-12, wherein forming the substrate further comprises:
   forming an outer solder resist layer on the top surface of the substrate; and
   forming a barrier between the first plurality of metal pads and the second plurality of metal pads.
14. The method of clause 13, wherein the barrier is a trench etched into the outer solder resist layer, the trench being filled by any excess of either the first resin, the second resin, or both.
15. The method of clause 13 or 14, wherein the barrier is a dam adjacent to the outer solder resist layer.

What is claimed is:

1. An integrated circuit (IC) package, comprising:
a die, comprising:
a plurality of first die interconnects extending in a vertical direction; and
a plurality of second die interconnects extending in the vertical direction;
a substrate having a top surface and extending in a horizontal direction, the substrate comprising an outer metallization layer, comprising:
a first plurality of metal pads coupled to the plurality of first die interconnects in a first region of the top surface; and
a second plurality of metal pads coupled to the plurality of second die interconnects in a second region of the top surface; and
a package mold layer extending in the horizontal direction and between the substrate and the die, comprising:
a first resin surrounding the plurality of first die interconnects; and
a second resin surrounding the plurality of second die interconnects.

2. The IC package of claim 1, wherein:
the plurality of first die interconnects have a first diameter; and
the plurality of second die interconnects have a second diameter, the second diameter greater than the first diameter.

3. The IC package of claim 2, wherein a ratio between the second diameter and the first diameter is between 1.7 and 2.5.

4. The IC package of claim 1, wherein:
the first resin is an anhydride-based resin; and
the second resin is an amine-based resin.

5. The IC package of claim 1, wherein the substrate further comprises:
an outer solder resist layer on the top surface of the substrate; and
a barrier between the first plurality of metal pads and the second plurality of metal pads.

6. The IC package of claim 5, wherein the barrier is a trench etched into the outer solder resist layer, the trench being filled by any excess of either the first resin, the second resin, or both.

7. The IC package of claim 5, wherein the barrier is a dam adjacent to the outer solder resist layer.

8. The IC package of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

9. A method of fabricating an integrated circuit (IC) package, comprising:
forming a die, comprising:
a plurality of first die interconnects extending in a vertical direction; and
a plurality of second die interconnects extending in the vertical direction;
forming a substrate having a top surface and extending in a horizontal direction, comprising:
forming an outer metallization layer, comprising:
a first plurality of metal pads coupled to the plurality of first die interconnects in a first region of the top surface; and
a second plurality of metal pads coupled to the plurality of second die interconnects in a second region of the top surface; and
forming a package mold layer extending in the horizontal direction and between the substrate and the die, comprising:
a first resin surrounding the plurality of first die interconnects; and
a second resin surrounding the plurality of second die interconnects.

10. The method of claim 9, wherein:
the plurality of first die interconnects have a first diameter; and
the plurality of second die interconnects have a second diameter, the second diameter greater than the first diameter.

11. The method of claim 10, wherein a ratio between the second diameter and the first diameter is between 1.7 and 2.5.

12. The method of claim 9, wherein:
the first resin is an anhydride-based resin; and
the second resin is an amine-based resin.

13. The method of claim 9, wherein forming the substrate further comprises:
forming an outer solder resist layer on the top surface of the substrate; and
forming a barrier between the first plurality of metal pads and the second plurality of metal pads.

14. The method of claim 13, wherein the barrier is a trench etched into the outer solder resist layer, the trench being filled by any excess of either the first resin, the second resin, or both.

15. The method of claim 13, wherein the barrier is a dam adjacent to the outer solder resist layer.
